(19) United States
(12) Patent Application Publication
(10) Pub. No.: US 2020/0386692 A1
(43) Pub. Date: Dec. 10, 2020

(54) MULTI-IMAGE PARTICLE DETECTION SYSTEM AND METHOD

(71) Applicant: ASML HOLDING N.V., Veldhoven (NL)

(72) Inventors: Aage BENDIKSEN, Fairfield, CT (US); Guobin OU, Westport, CT (US); Michael Christopher KOCHANSKI, Sandy Hook, CT (US); Michael Leo NELSON, Redding, CT (US)

(21) Appl. No.: 16/471,518

(22) PCT Filed: Dec. 19, 2017
(86) PCT No.: PCT/EP2017/083432

§ 371 Date: Jun. 19, 2019

Related U.S. Application Data
(60) Provisional application No. 62/439,669, filed on Dec. 28, 2016.

(51) Int. Cl. G01N 21/95; G01N 21/88; G01N 21/956; G01N 21/94; G03F 1/84; G06T 7/00

(52) U.S. Cl. CPC G01N 21/9501; G01N 21/8806; G06T 7/0004; G01N 21/94; G03F 1/84; G01N 21/95607

(57) ABSTRACT

A method including: obtaining a first image location for an image feature of a first image of at least part of an object surface, obtaining a second image location for an image feature in a second image of at least part of the object surface, and/or obtaining a value of the displacement between the first and second image locations, the first and second images obtained at different relative positions between an image surface of a detector and the object surface in a direction substantially parallel to the image surface and/or the object surface; and determining, by a computer system, that a physical feature is at an inspection surface or not at the inspection surface, based on an analysis of the second image location and/or the displacement value and on an anticipated image feature location of the image feature in the second image relative to the first image location.

### CROSS-REFERENCE TO RELATED APPLICATIONS

This application claims priority of U.S. Provisional Patent Application No. 62/439,669, which was filed on Dec. 28, 2016, and which is incorporated herein in its entirety by reference.

### FIELD

The disclosure herein relates generally to inspection, for example, for particles on an object.

### BACKGROUND

A lithography apparatus can be used, for example, in the manufacture of integrated circuits (ICs). In such a case, a patterning device (e.g., a mask) may contain or provide a device pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern of the patterning device. In general, a single substrate contains a plurality of adjacent target portions to which the pattern is transferred successively by the lithography apparatus, one target portion at a time. In one type of lithography apparatus, the pattern of the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern of the patterning device are transferred to one target portion progressively. Since, in general, the lithography apparatus will have a magnification factor M (generally <1), the speed F at which the substrate is moved will be a factor M times that at which the projection beam scans the patterning device.

Prior to transferring the pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern of the patterning device to a substrate and typically, but optionally, involves one or more related pattern processing steps, such as resist development by a development apparatus, baking of the substrate using a bake tool, etching using the pattern using an etch apparatus, etc.

### SUMMARY

Particles or defects on a surface of an object, such as the patterning device, can generate pattern artefacts when the patterning device is used to print a pattern in a resist on a substrate. Additionally or alternatively, particles or defects can impact one or more other patterning processes. So, identifying particles and/or surface defects of an object used in a patterning process is desirable to enable, e.g., accurate patterning and improved device yield.

In an embodiment, there is provided a method comprising: obtaining a first image location for an image feature of a first image of at least part of an object surface, obtaining a second image location for an image feature in a second image of at least part of the object surface, and/or obtaining a value of the displacement between the first and second image locations, the first and second images obtained at different relative positions between an image surface of a detector of the images and the object surface in a direction substantially parallel to the image surface and/or the object surface; and determining, by a computer system, that a physical feature is at an inspection surface or not at the inspection surface, based on an analysis of the second image location and/or the displacement value and on an anticipated image feature location of the image feature in the second image relative to the first image location.

In an embodiment, there is provided a method comprising: obtaining a value of a first displacement between a first image location for an image feature of a first image of at least part of an object surface and a second image location for an image feature in a second image of at least part of the object surface, the first and second images obtained at different relative positions between an image surface of a detector of the images and the object surface in a direction substantially parallel to the image surface and/or the object surface; obtaining a value of a second displacement between the relative positions; and determining, by a computer system, a distance of a physical feature from the detector based on analysis of the first and second displacement values.

In an embodiment, there is provided an inspection apparatus for inspecting an object of a patterning process, the inspection apparatus being operable to perform a method as described herein.

In an embodiment, there is provided a computer program product comprising a computer non-transitory readable medium having instructions recorded thereon, the instructions when executed by a computer implementing a method as described herein.

In an embodiment, there is provided a system comprising: an inspection apparatus configured to provide a beam of radiation onto an object surface at an oblique angle to the object surface and to detect radiation scattered by a physical feature on the object surface; and a computer program product as described herein. In an embodiment, the system further comprises a lithographic apparatus comprising a support structure configured to hold a patterning device to modulate a radiation beam and a projection optical system arranged to project the modulated radiation beam onto a radiation-sensitive substrate, wherein the object is the patterning device.

These and other features of the present invention, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a”, “an”, and “the” include plural referents unless the context clearly dictates otherwise. In addition, as used in the specification and the claims, the term “or” means “and/or” unless the context clearly dictates otherwise.

### BRIEF DESCRIPTION OF THE DRAWINGS

Embodiments are illustrated by way of example, and not by way of limitation, in the figures of the accompanying drawing and in which like reference numerals refer to similar elements.

FIG. 1 depicts a schematic diagram of an embodiment of a lithographic apparatus;

FIG. 2 depicts a schematic diagram of an embodiment of a lithographic cell;

FIG. 3 is a schematic diagram of an inspection system, according to an embodiments;

FIG. 4 is a schematic diagram of transformation of reticle images, according to an embodiments;

FIG. 5 is a flow diagram of a method of inspecting an inspection surface, according to an embodiment;

FIG. 6 is a flow diagram of a processing method involving an inspection, according to an embodiment; and

FIG. 7 illustrates a block diagram of an example computer system.

### DETAILED DESCRIPTION

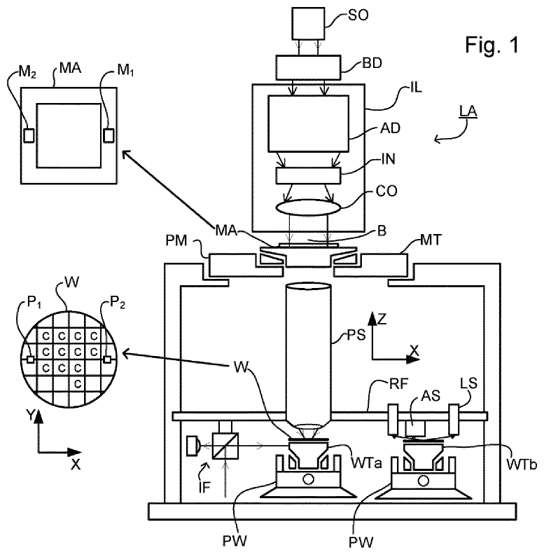

FIG. 1 schematically depicts a lithographic apparatus LA in association with which the techniques described herein can be utilized. The apparatus includes an illumination optical system (illuminator) IL configured to condition a radiation beam B (e.g., ultraviolet (UV), deep ultraviolet (DUV) or extreme ultraviolet (EUV) radiation), a patterning device support or support structure (e.g., a mask table) MT constructed to support a patterning device (e.g., a mask) MA and connected to a first positioner PM configured to accurately position the patterning device in accordance with certain parameters; one or more substrate tables (e.g., a wafer table) WTa, WTb constructed to hold a substrate (e.g., a resist coated wafer) W and connected to a second positioner PW configured to accurately position the substrate in accordance with certain parameters; and a projection optical system (e.g., a refractive, reflective, catoptric or catadioptric optical system) PS configured to project a pattern imparted to the radiation beam B by patterning device MA onto a target portion C (e.g., including one or more dies) of the substrate W.

The illumination optical system may include various types of optical components, such as refractive, reflective, magnetic, electromagnetic, electrostatic or other types of optical components, or any combination thereof, for directing, shaping, or controlling radiation. In this particular case, the illumination system also comprises a radiation source SO.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support may be a frame or a table, for example, which may be fixed or movable as required. The patterning device support may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix. As another example the patterning device comprises a LCD matrix.

As here depicted, the apparatus is of a transmissive type (e.g., employing a transmissive patterning device). However, the apparatus may be of a reflective type (e.g., employing a programmable mirror array of a type as referred to above, or employing a reflective mask (e.g., for an EUV system)).

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO (e.g., a mercury lamp or excimer laser, LPP (laser produced plasma) EUV source). The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the spatial and/or angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table) MT, and is patterned by the patterning device. Having traversed the patterning device (e.g., mask) MA, the radiation beam B passes through the projection optical system PS, which focuses the beam onto a target portion C of the substrate W, thereby projecting an image of the pattern on the target portion C. With the aid of the second positioner PW and position sensor IF (e.g., an interferometric device, linear encoder, 2-D encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using patterning device alignment marks M₁, M₂ and substrate alignment marks P₁, P₂. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the patterning device alignment marks may be located between the dies. Small alignment markers may also be included within dies, in amongst the device features, in which case it is desirable that the markers be as small as possible and not require any different imaging or process conditions than adjacent features. The alignment system, which detects the alignment markers, is described further below.

Lithographic apparatus LA in this example is of a so-called dual stage type which has two substrate tables WTa, WTb and two stations—an exposure station and a measurement station—between which the substrate tables can be exchanged. While one substrate on one substrate table is being exposed at the exposure station, another substrate can be loaded onto the other substrate table at the measurement station and various preparatory steps carried out. The preparatory steps may include mapping the surface control of the substrate using a level sensor LS, measuring the position of alignment markers on the substrate using an alignment sensor AS, performing any other type of metrology or inspection, etc. This enables a substantial increase in the throughput of the apparatus. More generally, the lithography apparatus may be of a type having two or more tables (e.g., two or more substrate tables, a substrate table and a measurement table, two or more patterning device tables, etc.). In such “multiple stage” devices a plurality of the multiple tables may be used in parallel, or preparatory steps may be carried out on one or more tables while one or more other tables are being used for exposures. Twin stage lithography apparatuses are described, for example, in U.S. Pat. No. 5,969,441, incorporated herein by reference in its entirety.

While a level sensor LS and an alignment sensor AS are shown adjacent substrate table WTb, it will be appreciated that, additionally or alternatively, a level sensor LS and an alignment sensor AS can be provided adjacent the projection system PS to measure in relation to substrate table WTa.

The depicted apparatus can be used in a variety of modes, including for example a step mode or a scan mode. The construction and operation of lithographic apparatus is well known to those skilled in the art and need not be described further for an understanding of embodiments of the present invention.

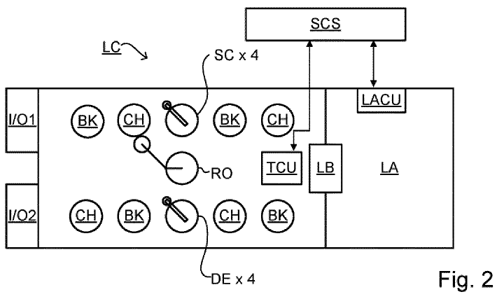

As shown in FIG. 2, the lithographic apparatus LA forms part of a lithographic system, referred to as a lithographic cell LC or a lithocell or cluster. The lithographic cell LC may also include apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

Deviations of a pattern on a substrate can occur when contamination (e.g., particles, foreign objects, etc.) and/or defects (e.g., scratches, surface variations, etc.) interfere with a pattern processing method. For example, a foreign object in or under a photoresist layer on a substrate can interfere with an exposure of a pattern during a lithography process. As another example, contamination and/or defects on a patterning device can block, diffract, etc. radiation and thus interfere with exposure of a pattern on a substrate during a lithography process.

Moreover, some objects may have measure to protect against contamination and/or defects. But those measures themselves may become contamination and/or have defects which can impact the patterning process. For example, a patterning device is often fitted with a pellicle (a protective covering) that reduces particulate contamination of a patterning device surface onto which exposure radiation is incident or through which radiation passes, and helps protect the patterning device surface from damage. A pellicle is typically separated from the patterning device surface, for example, by one or more mounting posts, so as to maintain a separation between the patterning device surface having the pattern and the backside of the pellicle. But, while a pellicle provides protection and reduces contamination of the pattern, the pellicle itself is susceptible to foreign objects and/or defects.

So, a lithography tool or a lithocell may have an inspection system that examines surfaces (inspection surfaces) for contamination and/or defects. Inspection surfaces can include a surface of a pellicle, a side of a patterning device having pattern (hereinafter for convenience the front side), a side of the patterning device opposite the side having the pattern (hereinafter for convenience the back side), a substrate (e.g. a semiconductor wafer), etc. The contamination and/or defects of an inspection surface is recorded by the inspection system. Amounts and/or locations of contamination and/or defects are monitored to determine, e.g., whether to perform a cleaning step, to replace an object within another object, to discontinue a manufacturing process, etc.

In an embodiment, an inspection system can identify contamination and/or defects by recording positions on the inspection surface where incident radiation is scattered toward a detector. A glancing, or low-incident angle, radiation tends to reflect off of an inspection surface in a direction away from a detector (e.g., a camera) looking for scattered radiation, while the scattered radiation propagates toward the detector. Thus, where the environment is otherwise relatively dark, contamination and/or defects can be detected as “bright” objects in a dark field. Effectively, the contamination and/or defects become their own respective radiation sources.

Now, a difficulty of inspection is misidentification of a feature below or above an inspection surface as a contaminant and/or defect located on the inspection surface. For example, inspection of a pellicle surface, i.e., an inspection surface, can result in detection of portions or elements of the pattering device pattern, e.g., located below the inspection surface (i.e., the pellicle surface), in addition to, if any, contaminants and/or defects on the pellicle inspection surface. So, confusion regarding the vertical position of an image feature (and the corresponding physical feature that generates the image feature) with regard to an inspection surface can lead to inspection system false alarms. False alarms regarding defects and/or contamination, according to the type of error, could cause premature stopping of patterning process, discarding of an object, excessive cleaning of an object, etc. and thus incur time, expense, lack of productivity and/or inefficiency.

According to the present disclosure, determining whether a physical feature (that generates an image feature) of an object is at an inspection surface is accomplished by recording and analyzing multiple images of at least part of the object at different relative shifts between the detector image plane/surface and the inspection surface, the shift being in a direction substantially parallel with the detector image plane/surface and/or the inspection surface. The physical feature can include a contaminant (such as a particle on a surface) and/or a defect (e.g., a scratch on a surface). In an embodiment, the physical feature interferes with radiation transmission, reflection or diffraction.

Based on a location of an image feature in a first image of the at least part of the object and an expected or actual location of the image feature in a second image of the at least part of the object, it can be determined whether the physical feature corresponding to the image feature is at the inspection surface (or not). This determination can then be used to decide whether to take any action (or not) with respect to the object.

In an embodiment, this determination can be based on analyzing the actual location of the image feature in the second image and determining from, e.g., a vector of the image feature from its position in the first image to its position in the second image, whether the physical feature corresponding to the image feature is at the inspection surface (or not).

In an embodiment, this determination can be based on whether the image feature in the second image appears at an expected location in the second image and if it does or does not, a corresponding determination can be made whether the physical feature corresponding to the image feature is at the inspection surface (or not). For example, based on a location of an image feature in a first image of at least part of the object, a separation distance between the detector and the inspection surface, and a relative shift between the detector image plane/surface and the inspection surface for a subsequent image of the at least part of the object, the shift being in a direction substantially parallel with the detector image plane/surface and/or the inspection surface, a physical feature that is on the inspection surface appears at a predictable location in the subsequent (second, third, etc.) image of the object. In this case, an image feature that does not appear at a predictable location in a subsequent image is a physical feature that is located away from the inspection surface in a direction substantially perpendicular to the inspection surface; in other words, the image feature is not at the inspection surface.

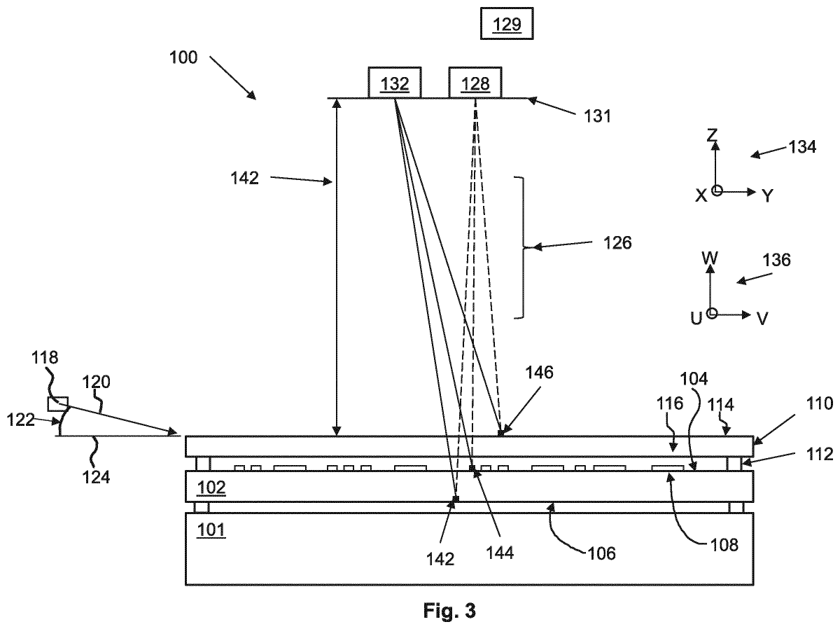

FIG. 3 is a schematic diagram of components of an inspection system 100, according to an embodiment. In this embodiment, the inspection system 100 is designed to inspect a patterning device or a pellicle of a patterning device. In an embodiment, the inspection system 100 can be used to inspect a different object. Further, this embodiment is depicted as inspecting an object from above. But, additionally or alternatively, the inspection system can inspect from any orientation, including from below or from the side.

Referring to FIG. 3, the inspection system comprises or uses an object support 101. In an embodiment, the object support 101 comprises an actuator to cause the object support 101 to be displaced. In an embodiment, the object support 101 can move in up to 6 degrees of freedom. In an embodiment, the object support 101 moves at least in the X and/or Y directions, desirably in the X-Y plane. The object support 101 can be a dedicated object support for the inspection system or an existing object support in an apparatus (e.g., a lithographic apparatus).

On the object support 101, the object to be inspected is provided. In an embodiment, the object comprises a patterning device 102. The patterning device 102 here has a patterning device front side or surface 104 and a patterning device back side or surface 106. In this example, the patterning device 102 comprises an at least partially transparent substrate with an absorber (e.g., a chrome absorber) in the form of the patterning device pattern 108 on the patterning device front side 104. Further, in this embodiment, the patterning device 102 has a pellicle 110 that at least partially covers the patterning device pattern 107. The pellicle 110 is offset by a gap from the patterning device pattern 108 by one or more pellicle supports 112. The pellicle 110 has a pellicle upper surface 114 and a pellicle lower surface 116, and is configured to allow illumination to travel through the pellicle 110 onto the patterning device pattern 108 (e.g., for a reflective patterning device, such as an EUV mask) and/or to allow illumination from the patterning device pattern 108 (e.g., a transmissive mask or a reflective mask). That is, the pellicle 110 is at least partially transparent.

In an embodiment, the object to be inspected has an inspection surface with respect to which it is desired to determine the presence (or absence) of a contaminant and/or a defect. In this example, the inspection surface is the pellicle surface 114. As will be appreciated, the inspection surface can be various other surfaces of the object to be inspected (e.g., the surface 106, surface 116, etc.).

To facilitate the inspection, a radiation output 118 is located at a side of the patterning device 102. In an embodiment, the radiation output 118 is a radiation source (e.g., a laser) to provide radiation or is connected to a radiation source. According to an embodiment, radiation output 118 includes a radiation outlet that continuously surrounds the patterning device or comprises multiple radiation outlets that spread around the object to be inspected so as to effectively surround the object. Radiation output 118 is positioned to allow incident radiation 120 to approach a horizontal surface of the patterning device 102 and/or the pellicle 110 at an incident angle 122 ranging from about 0.5 degrees to about 10 degrees. As discussed above, this can enable dark field inspection of the surface. The magnitude of the incident angle 122 is specified with respect to a reference plane 124, which here includes the inspection surface of the pellicle surface 114.

In an embodiment, the radiation comprises or is a wavelength of visible light. In an embodiment, the radiation is polarized.

Further, the inspection system comprises a detector 128 (e.g., a camera). In an embodiment, the detector 128 is connected to an actuator 129 to cause the detector 128 to be displaced. In an embodiment, the detector 128 can move in up to 6 degrees of freedom. In an embodiment, the detector 128 moves at least in the X and/or Y directions, desirably in the X-Y plane. In an embodiment, the object support 101 doesn't need to have an actuator if the detector 128 has actuator 129. Or, in an embodiment, the detector 128 doesn't need to have actuator 129 if the object support 101 has an actuator.

Detector 128 is configured to receive radiation from at least part of the object. For example, the detector 128 is configured to receive radiation from at least part of surface 114.

Further, while the detector 128 is shown above the surface 114 in this example, if a different surface were being inspected, then the detector 128 can assume an appropriate position. For example, if the surface 106 were inspected from the bottom in FIG. 3, then the output 118 can direct radiation on the surface 106 and detector 128 can be located below surface 106. Similarly, a detector 128 and an output 118 can be provided on opposite sides of the objects to the inspected (e.g., for inspection of the pellicle 110 and/or the front side of the patterning device 102 in combination with inspection of the back side of the patterning device 102).

So, a significant amount of the radiation 120 from output 118 will be specularly reflected from the surface 114. But, if there is a contaminant and/or defect on the surface 114, some the radiation 120 will be scattered by the contaminant and/or defect as radiation 126 and become incident on the detector 128 at a first relative position 130 of the detector 128 with respect to the surface 114.

But, at least some of the radiation 120 (or other radiation) can become incident on, e.g., the patterning device pattern 108, the lower surface 116 of the pellicle 110, etc. and radiation that is redirected by those surfaces or structures can also become part of radiation 126. Thus, it can be unclear whether radiation captured by detector 128 relates to a contaminant and/or defect on the surface 114 or is from a different surface.

So, as discussed above, to help distinguish whether radiation captured by detector 128 is from the surface 114 (or not), multiple images of at least part of the object to be inspected are obtained at different relative shifts between the detector image surface 131 and the inspection surface 114, the shift being in a direction substantially parallel with the detector image surface and/or the inspection surface. Those images are then analyzed to help determine whether radiation recorded in those images relates to the inspection surface 114 (or not).

To enable the capture of the multiple images, there can be a relative movement in the X and/or Y between the detector image plane/surface 131 and the inspection surface 114. In a preferred embodiment, this is accomplished by moving the detector 128 in the X and/or Y, while keeping the surface 114 essentially stationary. In an embodiment, the relative motion can be accomplished by moving the surface 114 in the X and/or Y, while keeping the detector 128 essentially stationary. In an embodiment, there can be a combination of motion by the detector 128 and the surface 114.

So, referring to FIG. 3, an example physical feature 146 of interest (e.g., a contaminant and/or a defect) located at the surface 114 is considered along with an example physical feature 142 located in this case at the surface 106 and a physical feature 144 located at the surface 104. In this example, radiation from each of these features becomes incident on the detector 128.

So, in an embodiment, a first image of at least part of the object to be inspected is captured with the detector 128 at the first relative position 130. The image captures radiation from the physical features 142, 144 and 146. The corresponding radiation in the image for each physical feature is referred to as an image feature.

Then, there is the relative motion between the detector image plane/surface 131 and the inspection surface 114 so that the detector 128 is at a second relative position 132. A second image is captured of the at least part of the object with the detector 128 at the second relative position 132. In this case, the second image captures radiation from radiation from the physical features 142, 144 and 146. It could be that one or more of the physical features 142, 144, and 146 are no longer captured, but desirably at least one of the physical features is still captured. As will be appreciated, further images can be captured at further relative positions.

So, as seen in FIG. 3, radiation 126 from the physical features 142, 144, and 146 reaches the detector 128 at different angles that is a function of at least the relative shift between the detector image plane/surface 131 and the inspection surface 114 and the distance between the detector image plane/surface 131 and the physical features. So, by reaching detector 128 at different angles from the radiation redirecting physical features due to a combination of a certain displacement in the X-Y plane and different relative Z positions, radiation 126 originating from the physical features will have different relative displacements in the images, e.g., a first image feature corresponding to physical feature 142 can shift 3 pixels, a second image feature correspond to physical feature 144 can shift 4 pixels and a third image feature correspond to physical feature 146 can shift 5 pixel even each was subject to a same displacement in the X-Y plane. So, using these different relative displacements, it can be identified whether an image feature corresponds to surface 114 (or not).

To facilitate this analysis, the position of the physical features 142, 144, 146, and the position of detector 128, can be defined with a first coordinate system 134 (a world coordinate system). First coordinate system 134 includes the X, Y, and Z axes. The positions of image features (corresponding to the physical features) in the images generated by the detector 128 are described by a second coordinate system 136 (an image coordinate system). The second coordinate system 136 includes at least two perpendicular axes: a U-axis (in an embodiment, parallel to the X-axis), and a V-axis (in an embodiment, parallel to the Y-axis). Optionally, the second coordination system 136 includes a W-axis (in an embodiment, parallel to the Z-axis) perpendicular to the U and V axes. According to an embodiment, the Z-axis and the W-axis pass through respective origins of the first and second coordinated systems. In an embodiment, the origin of the second coordinate system is at a nominal center of the detector and a nominal center of the object to the inspected. However, the origins can be located elsewhere or not be aligned.

So, a separation distance 142 between the detector image plane/surface 131 and the inspection surface 114 is specified. This distance can be used later to facilitate determination of whether a physical feature is at the inspection surface (or not). While the distance between the detector image plane/surface 131 and the inspection surface 114 is used in this embodiment, it can be specified between the detector image plane/surface 131 and a different surface. In that case, such a separation distance can be used to determine whether the physical feature is not on the inspection surface 114 (but may not be able identify whether the physical feature at the inspection surface 114). According to an embodiment, the separation distance 142 can be selected from the range of about 75 mm to about 250 mm, e.g., in the range of about 120 mm to 200 mm.

Thus, a location of each physical feature 142, physical feature 144, and physical feature 146 is described using first coordinate system 134, where a position of the physical feature is described by a position (X, Y, Z) (a feature coordinate), where the (X, Y) coordinates describe a location on a surface of the object to be inspected relative to the origin of the first coordinate system 134, and a Z-coordinate describes a vertical position of the feature with respect to the origin of the first coordinate system 134. In an example, physical feature 146 has a first feature coordinate (x₁, y₁, z₁), physical feature 144 has a second feature coordinate (x₂, y₂, z₂), and physical feature 142 has a third feature coordinate (x₃, y₃, z₃), where z₃>z₂>z₁ or where z₁>z₂>z₃ where z₁=0.

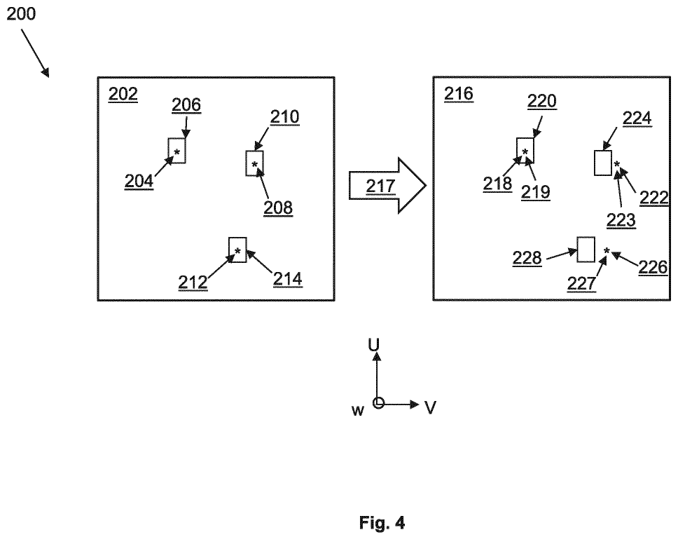

FIG. 4 is a diagram of a transformation 200 between a first image 202, taken from a first relative position between the detector image plane/surface and the inspection surface, and a second image 216, taken from a different, second relative position between the detector image plane/surface and the inspection surface. The first image 202 is an image of at least part of the object to be inspected (and is a baseline image, to which the second image 216 is compared) and includes three image features (first image features): first image feature 204, at first image location 206, first image feature 208, at first image location 210, and first image feature 212, at location 214. Each of the first image features corresponds to a physical feature at the object. In an embodiment, the image 202 is recorded by detector 128 at the first relative position 130.

The second image 216 is recorded by a detector at a different, second relative position between the detector image plane/surface and the inspection surface, than the relative position between the detector image plane/surface and the inspection surface for the first image 202. In an embodiment, the second relative position involves a shift 217 in a direction substantially parallel with the detector image plane/surface (e.g., in the X-Y plane) and/or the inspection surface (e.g., in the X-Y plane). So, like the first image 202, the second image 216 includes three second image features: second image feature 218 at second image location 219, second image feature 222 at second image location 223, and second image feature 226 at second image location 227. Each of the second image features corresponds to a physical feature at the object. In particular, in an embodiment, the second image feature 218 corresponds to the first image feature 204 and corresponds to a same physical feature. In an embodiment, the second image feature 222 corresponds to the first image feature 208 and corresponds to a same physical feature. In an embodiment, the second image feature 226 corresponds to the first image feature 212 and corresponds to a same physical feature.

In an embodiment, to determine whether a physical feature is located at the inspection surface 114 (or not), an anticipated image feature location of one or more of the second image features can be provided in relation to the associated one or more first image features. In an embodiment, an anticipated image feature location can be provided for each of the first and/or second image features. As discussed in further detail hereafter, the one or more anticipated image feature locations are generated (e.g., calculated) based on the first image location (e.g., first image location 206, first image location 210, and/or first image location 214, as applicable), a separation distance between the detector image plane/surface and the inspection surface, and a shift (including distance and/or direction) between the first relative position and the second relative position.

So, examples of anticipated image feature locations are shown as anticipated image feature locations 220, 224 and 228, wherein the anticipated image feature locations correspond respectively to first image feature 204, first image feature 208, and first image feature 212. Each of the anticipated image feature locations are based on the same separation distance. Thus, it is assumed that the physical feature for each first image feature is located at the inspection surface. While the anticipated image feature locations are primarily discussed above for convenience in relation to an area, the analysis with respect to anticipated image feature locations could alternatively or additionally be analyzed in terms of a displacement value relative to the applicable first image location or in terms of one or more position coordinates.

So, in FIG. 4, it can be seen that the anticipated image feature location 220 coincides with the second image location 219, indicating that the physical feature that generated second image feature 218 is located at the specified separation distance between the detector image plane/surface and the inspection surface (i.e., at the inspection surface). However, anticipated image feature location 224 does not coincide with second image location 223, and anticipated image feature location 228 does not coincide with second image location 227. The discrepancy between anticipated image feature location 224 and second image location 223, and between anticipated image feature location 228 and second image location 227, indicates that the physical features responsible for second image features 222 and 226 are not at the specified separation distance (i.e., not at the inspection surface).

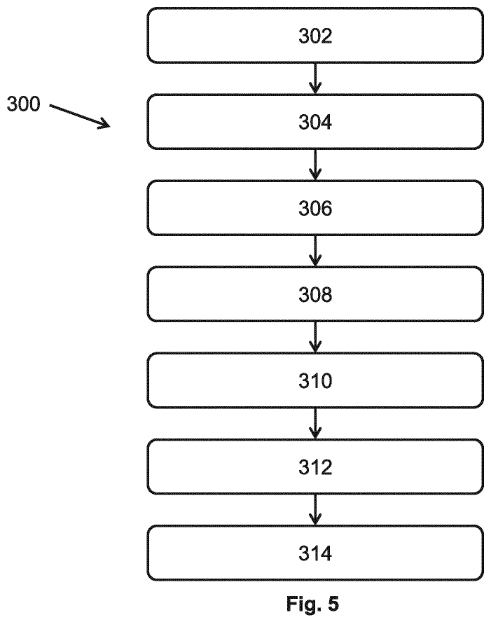

FIG. 5 is a flow diagram of an embodiment of a method 300 of determining whether contaminant and/or defect is at an inspection surface. At operation 302, a first image of at least part of the object to be inspected is recorded by a detector at a first relative position between the detector image plane/surface and the inspection surface.

At operation 304, a second image of at least part of the object to be inspected is recorded by the detector at a second relative position between the detector image plane/surface and the inspection surface. In an embodiment, the second relative position involves a shift 217 in a direction substantially parallel with the detector image plane/surface (e.g., in the X-Y plane) and/or the inspection surface (e.g., in the X-Y plane). In an embodiment, shift is selected from the range of about 1 mm to about 25 mm.

At operation 306, an image location (first feature location) for one or more image features of the first image (first image feature) is obtained. At operation 308, an image location (second feature location) for one or more image features of the second image (second image feature) is obtained.

At operation 310, an anticipated image feature location is determined for the second image feature of the second image corresponding to the first image feature of the first image. For example, the anticipated image feature location can be calculated as described below (e.g., calculated based on the shift between the first and second relative positions and a separation distance between the detector image plane/surface and the inspection surface), obtained through a calibration process (where, for example, a known physical feature on the inspection surface is observed as respective image features in images obtained at a fixed distance between the detector and the inspection surface and with known shift 217 between image captures and then the image feature displacement between the images is determined and used as an anticipated image feature location), etc.

At operation 312, the second feature location is compared to the anticipated image feature location determined for the second image feature of the second image. At operation 314, responsive to a determination that the second feature location corresponds to the anticipated image feature location, a physical feature corresponding to second image feature is classified as being on the inspection surface. Additionally or alternatively, responsive to a determination that the second feature location does not correspond to the anticipated image feature location, a physical feature corresponding to second image feature is classified as not being on the inspection surface.

As will be appreciated, the first feature locations from the first image, and second feature locations from the second image, are retained in a storage medium, such as a computer memory, in order to facilitate use of the first feature location when calculating an anticipated image feature location, or in order to compare the second feature location to the calculated anticipated image feature location, etc.

In an embodiment, an anticipated image feature location can be associated with a positional tolerance linked to the size and/or brightness of the image feature. Large and/or bright image features in the first image or the second image may use a lower tolerance to assess whether an anticipated image feature location corresponds to an actual image feature location (second feature location) in a second image.

In an embodiment, the first image and the second image are recorded at a same separation distance between the detector image plane/surface and the inspection surface and determination of the anticipated image feature location of an image feature in another image is based on a common distance between the detector image plane/surface and the inspection surface. In an embodiment, different separation distances could be used with an appropriate determination or correction of the anticipated image feature location.

In a non-limiting example of calculations to help assess whether a physical feature is at an inspection surface, the position in image coordinates of any observed image feature, such as physical features as described above, can be described in coordinates (u, v) in the U-V coordinate system. If the observed image feature at (u, v) originates from a point on a surface of an object at coordinates (x, y, z) in the X-Y-Z coordinate system, then if the X-Y-Z coordinate system with an origin at the detector and the U and V axes of the U-V-W coordinate system aligned with the X and Y axes, then the following relationships holds:

u=f x/z (1)

v=f y/z (2)

where f is the focal length of a lens of the detector (according to at least a pinhole model of image collection by a detector) and z is the distance between the detector and the surface feature being imaged. The “pinhole camera” model is perhaps the simplest camera model that can be applied to use in a stereo depth analysis approach described herein. However, the same stereo depth analysis approach can be used with more complex detector models which account for distortion and/or other optical effects not included in the simple pinhole camera model.

So, applying these relationships to contaminant or defect detection, they can enable the discrimination of physical features (e.g., particles, surface defects, patterning device pattern elements, etc.) on distinct surfaces (such as a patterning device back side, a patterning side front side, a pellicle, etc.) since each such surface is at a different distance with respect to the detector.

For example, if multiple images of the object to be inspected are taken with different relative X and/or Y positions between the detector image plane/surface and the inspection surface (i.e., the object), while maintaining a relatively constant separation in the Z direction, then the image coordinates (u, v) in the U-V coordinate system of each image feature corresponding to a physical feature on the object will change from one image to the another due to the change in X and/or Y. The distance in image coordinates that an image feature moves from one image to the another depends on the separation distance from the detector to the surface on which the feature lies, in accordance with the pinhole camera model above. This effect is often referred to as parallax.

So, in an embodiment, an anticipated image feature location can be determined based on an expected or measured distance from the detector image plane/surface and the inspection surface and be compared with an image feature displacement between images. For example, the displacement of an image feature position from one image to another image can be computed and compared to the displacement expected if the physical feature corresponding to the image feature was on an inspection surface at a certain Z distance from the detector and there was a known relative displacement between the inspection surface and the detector in the X-Y plane.

So, to determine an anticipated image feature location of an image feature in a second image, the change in an image feature coordinate position can be given as:

Δu₁=f Δx/z₁ (3)

Δv₁=f Δy/z₁ (4)

where (u₁, v₁) describes the image location of an image feature in the U and V coordinate system of the image feature and corresponds to a physical feature in the X, Y and Z coordinate system, Δu₁ describes the change in the U-direction of the image feature between the first and second images, Δv₁ describes the change in the V-direction of the image feature between the first and second images, Δx describes the change in the X-direction between the detector image plane/surface and the inspection surface, Δy describes the change in the Y-direction between the detector image plane/surface and the inspection surface, z₁ is the separation distance between the detector image plane/surface and the inspection surface, and f is the focal length of a lens of the detector (according to at least a pinhole model of image collection by a detector). So, when the coordinate of the image feature (u₁′/v₁′) in the second image equals (u₁+Δu₁, v₁+Δv₁) in response to a displacement of Δx and Δy, the physical feature is on the inspection surface (which is at a separation distance z₁ from the detector image plane/surface). When (u₁′, v₁′)≠(u₁+Δu₁, v₁+Δv₁) in response to a displacement of Δx and Δy, the physical feature is not at the inspection surface. Thus, Δu₁ and Δv₁ can be used as a classifier.

So, for example given image features detected in a first image at (u₁, v₁) and image features detected in a second image at (u₁′, v₁′) taken with a displacement of Δx and Δy, then:

For every feature (u₁, v₁) in the first image, search every feature (u₁′, v₁′) in the second image:

If (u₁′, v₁′) satisfies ((u₁+Δu₁)−u₁′)²+((v₁+Δv₁)−v₁′)²)<Tolerance

(u₁, v₁) is on the inspection surface

Else

(u₁, v₁) is not on the inspection surface

wherein Tolerance provides a threshold of maximum deviation from the anticipated image feature location (e.g., due to limitations arising from the size of the detector pixels). Of course, the condition need not be the addition of squares. It could be a square root of the squares or other formulation.

And, while the mathematical description of image feature displacement given above can be used to predict directly the expected image coordinate change of an image feature, or to compute the distance between the detector and the one or more image features seen in the images, it is also possible to use the parallax technique to discriminate which surface a feature is on without doing these computations directly. Rather, a calibration technique as described above can be used. For example, a known physical feature on the inspection surface is observed as respective image features in images taken at a fixed Z distance from the detector and a known X-Y shift. The image feature displacement between the images in response to the known X-Y shift is determined and used as an anticipated image feature location. That is, the calibration process can effectively yield classifiers Δu₁ and Δv₁ described above and can be used in any of the techniques herein during detection operations to determine which one or more features are on an inspection surface (at the expected Z distance), and which one or more features are on another surface (not at the expected Z distance).

Additionally or alternatively, the distances from the image detector to one or more measured physical features can be determined and then those matching a certain distance or a range with respect to that distance can be classified as being at an inspection surface (or not). So, if a first surface is at a distance z1 and a second surface is at a distance z2, the change in the image coordinate position of a physical feature on each surface is:

Δu₁=f Δx/z₁ (5)

Δv₁=f Δy/z₁ (6)

Δu₂=f Δx/z₂ (7)

Δv₂=f Δy/z₂ (8)

where (u₁, v₁) describes the image location of a first image feature in the U and V coordinate system and the image feature corresponds to a physical feature in the X, Y and Z coordinate system on the first surface, (u₂, v₂) describes the image location of a second image feature in the U and V coordinate system and the image feature corresponds to a physical feature in the X, Y and Z coordinate system on the second surface, Δu₁ describes the change in the U-direction of the first image feature between the first and second images, Δv₁ describes the change in the V-direction of the first image feature between the first and second images, Δu₂ describes the change in the U-direction of the second image feature between the first and second images, Δv₂ describes the change in the V-direction of the second image feature between the first and second images, Δx describes the change in the X-direction between the detector image plane/surface and the inspection surface, Δy describes the change in the Y-direction between the detector image plane/surface and the inspection surface, z₁ is the separation distance between the detector image plane/surface and the first surface, z₂ is the separation distance between the detector image plane/surface and the first surface, and f is the focal length of a lens of the detector (according to at least a pinhole model of image collection by a detector).

So, the change in image coordinate position is directly related to the difference in Z position between the first and second surfaces. Thus, in an embodiment, the Z position of each physical feature can be computed based on the observed image to image displacement (Δu₁, Δv₁, Δu₂, Δv₂) of the corresponding image feature between the images. Thus, the one or more image features with a determined Z position that corresponds to an expected or measured (e.g., measured by an interferometer) Z position between the detector and the inspection surface can be used to classify the associated physical feature as being at the inspection surface. A tolerance range with respect to the determined Z position and/or the expected or measured Z position can be specified such that a match within the tolerance range will cause the applicable physical feature to be at the inspection surface. Further, if a determined Z position doesn't match the expected or measured Z position of the inspection surface (including its optional tolerance range), then the applicable physical feature can be classified as not being at the inspection surface or another surface can be identified for the applicable physical feature, e.g., by measuring a distance from the detector to the object to identify a comparable surface, from knowledge of the expected Z position of one or more other surfaces to the detector, from knowledge of a difference in Z position between the inspection surface and another surface of the object, etc.

The above simple pinhole camera model does not model lens distortion, but when distortion is an issue, correction for distortion (e.g. radial correction coefficients) can be applied to image coordinates to produce “undistorted” image coordinates before applying the pinhole camera model. Or, the equations above can be extended to directly include distortion in the camera model.

In some embodiments, the parallax of image features on the inspection surface is twice as large as parallax of image features of physical features on a nearest surface spaced in a direction perpendicular to the inspection surface. In some embodiments, the parallax of image features of inspection surface physical features ranges from about 1.5 to about 6 times larger than the parallax of image features of physical features on a nearest surface below the inspection surface.

So, in an embodiment, there is provided a method of identifying a physical feature at an object surface that involves recording a first image and a second image of at least part of the object at respectively different relative positions between the detector and the object and responsive to determining a location of an image feature in the second image corresponds to an anticipated image feature location of the image feature in the first image, classifying the physical feature corresponding to the image feature as at an inspection surface of the object. In an embodiment, the anticipated image feature location is determined based on a separation of the relative positions and a separation distance between the inspection surface and the detector.

Embodiments of the methods and apparatus of the present disclosure can in principle be used for the inspection of any type of object, not just a lithographic patterning device. The methods and apparatus can be used for detection of particles and/or defects on any side of an object, including, e.g., a patterned side of an object, such as a patterning device, with appropriate context information (e.g., using relative heights or depths of surfaces on the patterned side to distinguish between an inspection surface and another surface).

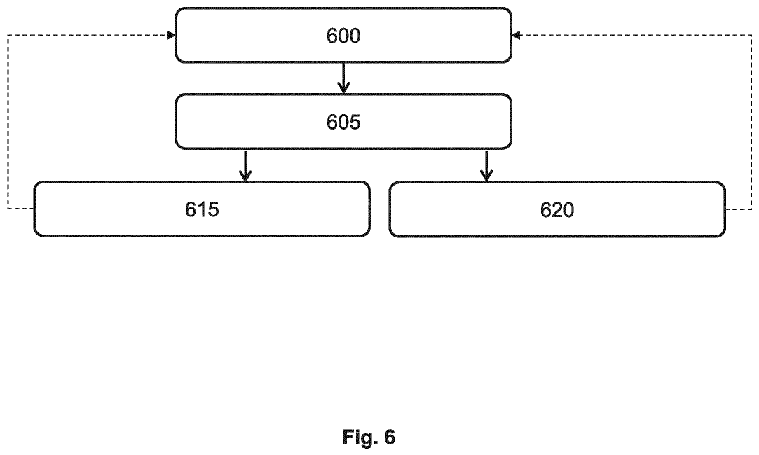

FIG. 6 shows an example of main process steps of an inspection regime applied to an object (such as a patterning device), using a patterning process apparatus such as the lithography apparatus shown in FIG. 1 or one or more apparatuses of the lithocell shown in FIG. 2. The process can be adapted to inspection of reticles and other patterning devices in other types of lithography, as well as to the inspection of objects other than lithography patterning devices.

An inspection apparatus, such as the apparatus of FIG. 3, may be integrated within the lithographic apparatus or other patterning process apparatus, so that the object under inspection is mounted on the same support structure (e.g. support structure MT) used during patterning process operations. The support structure may be moved to under the inspection apparatus, or equivalently the inspection apparatus is moved to where the object is already loaded. Or, the object may be removed from the immediate vicinity of its support structure to a separate inspection location where the inspection apparatus is located. This latter option avoids crowding the patterning process apparatus with additional equipment, and also permits the use of processes that would not be permitted or would be undesirable to perform within the patterning process apparatus itself. The inspection chamber can be closely coupled to the patterning process apparatus, or quite separate from it, according to preference.

An object, such as a patterning device, used in the patterning process is loaded at 600 into the inspection apparatus (or the inspection apparatus is brought to where the object is already loaded). Prior to inspection, the object may or may not have been used in the patterning process. Using the inspection apparatus, a plurality of images are obtained at 605.

At 610, a processing unit analyses the inspection images as described above in relation to FIGS. 3-5 above. As discussed above, the processing can determine whether a particle or defect is in or on a surface of interest. The processing unit can then make a decision about further processing of the object. If the object is found to be clean or defect-free, it is released at step 615 for use in the patterning process. As indicated by the dashed line, the object can return for inspection at a later time, after a period of operation. If the analysis at 610 indicates that cleaning, repair or disposal of the object is required, a cleaning, repair or disposal process is initiated at 620. After this process, the object (or a new object) may be released automatically for re-use, or returned for inspection to confirm success of the process as shown by the dashed line. Another potential outcome of the analysis at step 610 is to instruct additional inspection. For example, a more robust inspection can be performed by, for example, a different inspection apparatus in the patterning system. Or, the object may be taken out of the pattern system and inspected more thoroughly using other tools, e.g., SEM (scanning electron microscope). This may be to discriminate between different sizes of particles and/or different defect types, either for diagnosis of problems in the patterning process or a patterning process apparatus or to decide, in fact, the object can be released for use.

As mentioned already the inspection apparatus can be provided as an in-tool device, that is, within a patterning process apparatus, or as a separate apparatus. As a separate apparatus, it can be used for purposes of object inspection (e.g., prior to shipping). As an in-tool device, it can perform a quick inspection of an object prior to using the object in or for a patterning process step. It may in particular be useful to perform inspections in between executions of the patterning process, for example to check after every N exposures whether the patterning device is still clean.

Processing of signals in or from the inspection apparatus may be implemented by a processing unit implemented in hardware, firmware, software, or any combination thereof. The processing unit may be the same as a control unit of the patterning process apparatus, or a separate unit, or a combination of the two.

Thus, an embodiment, it is recognized that an object to be inspected can have multiple surfaces on which physical features are located. So, inspection desirably identifies a physical feature (e.g., a defect, a particle, etc.) on a particular surface. But in many cases it may be difficult to discriminate which physical feature seen in an image originates on which surface of the object (e.g., in the case of a patterning device, whether on a patterning device back side, a patterning device front side, a pellicle surface, etc.) That is, the physical features on surfaces other than an inspection surface can appear in the imagery. So, it is difficult for an inspection system to reliably determine, e.g., particles and/or defects that appear on different surfaces, and/or to distinguish particles and/or defects from expected physical features (e.g., a pattern on a patterning device).

So, in an embodiment, multiple images of an object to be inspected are obtained at different relative positions between the detector and the object at, for example, a fixed distance between the detector and the object, and those images are analyzed to: a) recover the absolute or relative depths of each observed physical feature, and/or b) determine whether an observed physical feature is from an intended surface under inspection.

By using such a “stereo imaging” approach, it becomes possible to discern which visible features in the imagery originate on different surface. In this way, the inspection system can more reliably report, e.g., particles and/or defects on a target inspection surface, and be less likely to erroneously report physical features that did not come from the target inspection surface.

To recover the depth of an observed physical feature, its position in multiple images can be compared, and its change in position in image coordinates can be used to compute its depth relative to the detector. Once the depth of the physical feature is known, it can be assigned to a specific surface of the object based on the absolute or relative depths of the feature and the known absolute or relative position of the object to the detector.

In an embodiment, direct computing of the depth of one or more observed physical features can be avoided. Instead, it is analyzed how much an image feature corresponding to a physical feature moves from one image to the other. Physical features at a same distance from the detector are expected to move the same distance; physical features at different distances from detector will move a different distance in the images. So, if the expected image movement of a feature on a target inspection surface is known—either from computation or a calibration—then a physical feature not on the target inspection surface can be filtered out or a physical feature on the target inspection can be identified, by comparing the image feature displacement between images to an expected displacement for the target inspection surface.

So, in short, multiple images of the object at different relative positions between the detector and the object in a direction parallel to the surface of the object and/or detector image surface can be used to: a) recover relative depths of a detected physical feature from a movement of the image feature corresponding to the physical feature between the images, thus determining the surface at which it is located, and/or b) to use the observed change in image feature position between the images to filter out physical features not on the target inspection surface or to identify physical features as being on the target inspection surface.

An advantage of this approach is reliable particle and/or defect detection, specifically reduced false alarms due to the visibility of physical features not actually on a target inspection surface. False alarms can lead to unnecessary loss of production time, and thus delays in patterning process processing and/or higher cost of production. Thus, this technique can enable meeting of productivity targets for particle detection and/or reduction of false alarm rates.

In an embodiment, there is provided a method comprising: obtaining a first image location for an image feature of a first image of at least part of an object surface, obtaining a second image location for an image feature in a second image of at least part of the object surface, and/or obtaining a value of the displacement between the first and second image locations, the first and second images obtained at different relative positions between an image surface of a detector of the images and the object surface in a direction substantially parallel to the image surface and/or the object surface; and determining, by a computer system, that a physical feature is at an inspection surface or not at the inspection surface, based on an analysis of the second image location and/or the displacement value and on an anticipated image feature location of the image feature in the second image relative to the first image location.

In an embodiment, the first and second images are obtained at a substantially same distance between the image surface and the object surface. In an embodiment, the anticipated image feature location comprises an expected displacement between the first and second image locations. In an embodiment, the physical feature is a particle and/or a defect. In an embodiment, the method further comprises calculating the anticipated image feature location based on a displacement between the relative positions and an expected or measured distance between the image surface and the object surface. In an embodiment, the method further comprises obtaining the anticipated image feature location by a calibration comprising: measuring a known physical feature on a target surface a plurality of times to obtain a plurality of calibration images, each calibration image obtained at a different relative position between the image surface of the detector and the target surface in a direction substantially parallel to the image surface and/or the target surface and at a known distance between the target surface and the image surface of the detector; and determining a displacement of the position of image features, corresponding to the physical feature, between the images, the displacement corresponding to the anticipated image feature location. In an embodiment, the method further comprises measuring, using the detector, the first and second images. In an embodiment, the method further comprises moving the detector with respect to the object surface to provide the relative positions. In an embodiment, the object surface comprises a surface of a patterning device. In an embodiment, the obtaining and determining is performed for substantially all image features in the first and second images. In an embodiment, the determining comprises determining that a defect and/or defect is at the inspection surface based on an analysis that the second image location and/or the displacement value corresponds to the anticipated image feature location.

In an embodiment, there is provided a method comprising: obtaining a value of a first displacement between a first image location for an image feature of a first image of at least part of an object surface and a second image location for an image feature in a second image of at least part of the object surface, the first and second images obtained at different relative positions between an image surface of a detector of the images and the object surface in a direction substantially parallel to the image surface and/or the object surface; obtaining a value of a second displacement between the relative positions; and determining, by a computer system, a distance of a physical feature from the detector based on analysis of the first and second displacement values.

In an embodiment, the method further comprises determining, based on the distance, that the physical feature is at an inspection surface or not at the inspection surface. In an embodiment, the first and second images are obtained at a substantially same distance between the image surface and the object surface. In an embodiment, the physical feature is a particle and/or a defect. In an embodiment, the method further comprises measuring, using the detector, the first and second images. In an embodiment, the method further comprises moving the detector with respect to the object surface to provide the relative positions. In an embodiment, the object surface comprises a surface of a patterning device. In an embodiment, the obtaining and determining is performed for substantially all image features in the first and second images.

As will be appreciated by one of ordinary skill in the art, the present application may be embodied as a system, method, or computer program product. Accordingly, aspects of the present application may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present application may take the form of a computer program product embodied in any one or more computer readable medium(s) having computer usable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, device, or any suitable combination of the foregoing. More specific examples (a non-exhaustive list) of the computer readable medium would include the following: an electrical connection having one or more wires, a portable computer diskette, a hard disk, a random access memory (RAM), a read-only memory (ROM), an erasable programmable read-only memory (e.g. EPROM or Flash memory), an optical fiber, a portable compact disc read-only memory CDROM, an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in a baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Computer code embodied on a computer readable medium may be transmitted using any appropriate medium, including but not limited to wireless, wireline, optical fiber cable, radio frequency RF, etc., or any suitable combination thereof.

Computer program code for carrying out operations for aspects of the present application may be written in any combination of one or more programming languages, including an object oriented programming language such as Java™, Smalltalk™, C++, or the like, and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network LAN or a wide area network WAN, or the connection may be made to an external computer (for example, through the Internet using an Internet Service Provider).

The computer program instructions may also be loaded onto a computer, other programmable data processing apparatus, or other devices to cause a series of operational steps to be performed on the computer, other programmable apparatus, or other devices to produce a computer implemented process such that the instructions which execute on the computer or other programmable apparatus provide processes for implementing the functions/acts specified in the flowchart and/or block diagram block or blocks.

As noted above, it should be appreciated that the illustrative embodiments may take the form of an entirely hardware embodiment, an entirely software embodiment or an embodiment containing both hardware and software elements. In one example embodiment, the mechanisms of the illustrative embodiments may be implemented in software or program code, which includes but is not limited to firmware, resident software, microcode, etc.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modems and Ethernet cards are just a few of the currently available types of network adapters.

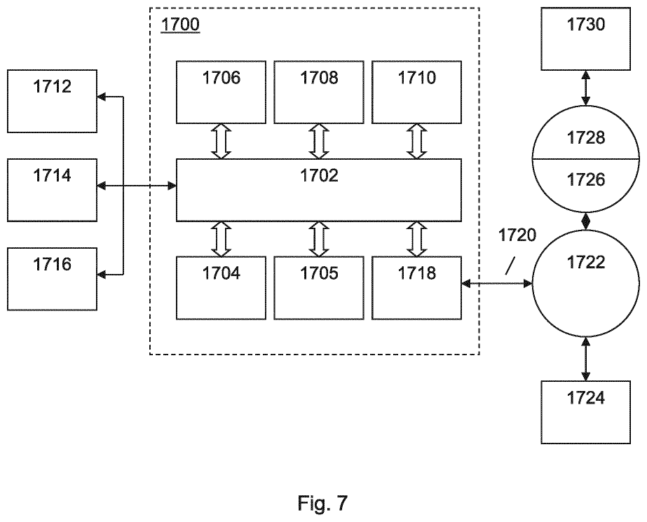

FIG. 7 shows a block diagram that illustrates an embodiment of a computer system 1700 which can assist in implementing any of the methods and flows disclosed herein. Computer system 1700 includes a bus 1702 or other communication mechanism for communicating information, and a processor 1704 (or multiple processors 1704 and 1705) coupled with bus 1702 for processing information. Computer system 1700 also includes a main memory 1706, such as a random access memory RAM or other dynamic storage device, coupled to bus 1702 for storing information and instructions to be executed by processor 1704. Main memory 1806 also may be used for storing temporary variables or other intermediate information during execution of instructions to be executed by processor 1704. Computer system 1700 further includes a read only memory ROM 1708 or other static storage device coupled to bus 1702 for storing static information and instructions for processor 1704. A storage device 1710, such as a magnetic disk or optical disk, is provided and coupled to bus 1702 for storing information and instructions.

Computer system 1700 may be coupled via bus 1702 to a display 1712, such as a cathode ray tube (CRT) or flat panel or touch panel display for displaying information to a computer user. An input device 1714, including alphanumeric and other keys, is coupled to bus 1702 for communicating information and command selections to processor 1704. Another type of user input device is cursor control 1716, such as a mouse, a trackball, or cursor direction keys for communicating direction information and command selections to processor 1704 and for controlling cursor movement on display 1712. This input device typically has two degrees of freedom in two axes, a first axis (e.g. x) and a second axis (e.g. y), that allows the device to specify positions in a plane. A touch panel (screen) display may also be used as an input device.

According to one embodiment, portions of a process described herein may be performed by computer system 1700 in response to processor 1704 executing one or more sequences of one or more instructions contained in main memory 1706. Such instructions may be read into main memory 1706 from another computer-readable medium, such as storage device 1710. Execution of the sequences of instructions contained in main memory 1706 causes processor 1704 to perform the process steps described herein. One or more processors in a multi-processing arrangement may also be employed to execute the sequences of instructions contained in main memory 1706. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1704 for execution. Such a medium may take many forms, including but not limited to, non-volatile media, volatile media, and transmission media. Non-volatile media include, for example, optical or magnetic disks, such as storage device 1710. Volatile media include dynamic memory, such as main memory 1706. Transmission media include coaxial cables, copper wire and fiber optics, including the wires that comprise bus 1702. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1704 for execution. For example, the instructions may initially be borne on a magnetic disk of a remote computer. The remote computer can load the instructions into its dynamic memory and send the instructions over a telephone line using a modem. A modem local to computer system 1700 can receive the data on the telephone line and use an infrared transmitter to convert the data to an infrared signal. An infrared detector coupled to bus 1702 can receive the data carried in the infrared signal and place the data on bus 1702. Bus 1702 carries the data to main memory 1706, from which processor 1704 retrieves and executes the instructions. The instructions received by main memory 1706 may optionally be stored on storage device 1710 either before or after execution by processor 1704.

Computer system 1700 may also include a communication interface 1718 coupled to bus 1702. Communication interface 1718 provides a two-way data communication coupling to a network link 1720 that is connected to a local network 1722. For example, communication interface 1718 may be an integrated services digital network ISDN card or a modem to provide a data communication connection to a corresponding type of telephone line. As another example, communication interface 1718 may be a local area network LAN card to provide a data communication connection to a compatible LAN. Wireless links may also be implemented. In any such implementation, communication interface 1718 sends and receives electrical, electromagnetic or optical signals that carry digital data streams representing various types of information.

Network link 1720 typically provides data communication through one or more networks to other data devices. For example, network link 1720 may provide a connection through local network 1722 to a host computer 1724 or to data equipment operated by an Internet Service Provider ISP 1726. ISP 1726 in turn provides data communication services through the worldwide packet data communication network, now commonly referred to as the “Internet” 1728. Local network 1722 and Internet 1728 both use electrical, electromagnetic or optical signals that carry digital data streams. The signals through the various networks and the signals on network link 1720 and through communication interface 1718, which carry the digital data to and from computer system 1700, are exemplary forms of carrier waves transporting the information.

Computer system 1700 can send messages and receive data, including program code, through the network(s), network link 1720, and communication interface 1718. In the Internet example, a server 1730 might transmit a requested code for an application program through Internet 1728, ISP 1726, local network 1722 and communication interface 1718. One such downloaded application may provide for a method or portion thereof as described herein, for example. The received code may be executed by processor 1704 as it is received, and/or stored in storage device 1710, or other non-volatile storage for later execution. In this manner, computer system 1700 may obtain application code in the form of a carrier wave.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”/“mask”, “wafer” or “die” in this text should be considered as interchangeable with the more general terms “patterning device”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

While the concepts disclosed herein may be used with systems and methods for imaging on a substrate such as a silicon wafer, it shall be understood that the disclosed concepts may be used with any type of lithographic systems, e.g., those used for imaging on substrates other than silicon wafers.

The description of the present application has been presented for purposes of illustration and description, and is not intended to be exhaustive or limiting of the invention in the form disclosed. Many modifications and variations will be apparent to those of ordinary skill in the art. Thus, it will be apparent to one skilled in the art that modifications may be made as described without departing from the scope of the claims set out below.

1. A method comprising:
obtaining a first image location for an image feature of a first image of at least part of an object surface;
obtaining at least one of a second image location for an image feature in a second image of at least part of the object surface and a value of a displacement between the first and second image locations, the first and second images being obtained at different relative positions between an image surface of a detector of the images and the object surface in a direction substantially parallel to the image surface and/or the object surface; and
determining, using a computer system, that a physical feature is at an inspection surface or not at the inspection surface, based on an analysis of the second image location or the displacement value or both and on an anticipated image feature location of the image feature in the second image relative to the first image location.

2. The method of claim 1, wherein the first and second images are obtained at a substantially same distance between the image surface and the object surface.

3. The method of claim 1, wherein the anticipated image feature location comprises an expected displacement between the first and second image locations.

4. The method of any of claim 1, wherein the physical feature is a particle or a defect.

5. The method of any of claim 1, further comprising calculating the anticipated image feature location based on a displacement between the relative positions and an expected or measured distance between the image surface and the object surface.

6. The method of claim 1, further comprising obtaining the anticipated image feature location by a calibration comprising:
measuring a known physical feature on a target surface a plurality of times to obtain a plurality of calibration images, each calibration image obtained at a different relative position between the image surface of the detector and the target surface in a direction substantially parallel to the image surface and/or the target surface and at a known distance between the target surface and the image surface of the detector; and
determining a displacement of the position of image features, corresponding to the physical feature, between the images, the displacement corresponding to the anticipated image feature location.

7. The method of claim 1, further comprising measuring, using the detector, relative positions of the first and second images.

8. The method of claim 7, further comprising moving the detector with respect to the object surface to provide the relative positions.

9. The method of claim 1, wherein the object surface comprises a surface of a patterning device.

10. The method of claim 1, wherein the obtaining and determining is performed for substantially all image features in the first and second images.

11. The method of claim 1, wherein the determining comprises determining that a particle and/or defect is at the inspection surface based on an analysis that the second image location and/or the displacement value corresponds to the anticipated image feature location.

12. A method comprising:
obtaining a value of a first displacement between a first image location for an image feature of a first image of at least part of an object surface and a second image location for an image feature in a second image of at least part of the object surface, the first and second images being obtained at different relative positions between an image surface of a detector of the images and the object surface in a direction substantially parallel to the image surface and/or the object surface;
obtaining a value of a second displacement between the relative positions; and
determining, using a computer system, a distance of a physical feature from the detector based on analysis of the first and second displacement values.

13. The method of claim 12, further comprising determining, based on the distance, that the physical feature is at an inspection surface or not at the inspection surface.

14. The method of claim 12, wherein the first and second images are obtained at a substantially same distance between the image surface and the object surface.

15. The method of claim 12, wherein the physical feature is a particle or a defect.

16. The method of claim 12, further comprising measuring, using the detector, relative positions of the first and second images.

17. The method of claim 16, further comprising moving the detector with respect to the object surface to provide the relative positions.

18. The method of claim 12, wherein the object surface comprises a surface of a patterning device.

19. The method of claim 12, wherein the obtaining and determining is performed for substantially all image features in the first and second images.

20. An inspection apparatus for inspecting an object of a patterning process, the inspection apparatus comprising:
means for obtaining a first image location for an image feature of a first image of at least part of an object surface;
means for obtaining at least one of a second image location for an image feature in a second image of at least part of the object surface, and a value of a displacement between the first and second image locations, the first and second images being obtained at different relative positions between an image surface of a detector of the images and the object surface in a direction substantially parallel to the image surface and/or the object surface; and
means comprising a computer system for determining that a physical feature is at an inspection surface or not at the inspection surface, based on an analysis of the second image location and/or or the displacement value or both and on an anticipated image feature location of the image feature in the second image relative to the first image location.

21. A computer program product comprising a computer non-transitory readable medium having instructions recorded thereon, the instructions when executed by a computer implementing a method comprising the steps of:
obtaining a first image location for an image feature of a first image of at least part of an object surface;
obtaining at least one of a second image location for an image feature in a second image of at least part of the object surface, and a value of a displacement between the first and second image locations, the first and second images being obtained at different relative positions between an image surface of a detector of the images and the object surface in a direction substantially parallel to the image surface and/or the object surface; and
determining that a physical feature is at an inspection surface or not at the inspection surface, based on an analysis of the second image location and/or or the displacement value or both and on an anticipated image feature location of the image feature in the second image relative to the first image location.

22. A system comprising:
an inspection apparatus configured to provide a beam of radiation onto an object surface at an oblique angle to the object surface and to detect radiation scattered by a physical feature on the object surface; and
a computer program product comprising a computer non-transitory readable medium having instructions recorded thereon, the instructions when executed by a computer implementing a method comprising the steps of:
obtaining a first image location for an image feature of a first image of at least part of an object surface;
obtaining at least one of a second image location for an image feature in a second image of at least part of the object surface, and a value of a displacement between the first and second image locations, the first and second images being obtained at different relative positions between an image surface of a detector of the images and the object surface in a direction substantially parallel to the image surface and/or the object surface; and
determining that a physical feature is at an inspection surface or not at the inspection surface, based on an analysis of the second image location and/or or the displacement value or both and on an anticipated image feature location of the image feature in the second image relative to the first image location.

23. The system of claim 22, further comprising a lithographic apparatus comprising a support structure configured to hold a patterning device to modulate a radiation beam and a projection optical system arranged to project the modulated radiation beam onto a radiation-sensitive substrate, wherein the object is the patterning device.
